(19) United States
(12) Patent Application Publication
(10) Pub. No.: US 2012/0325146 A1
(43) Pub. Date: Dec. 27, 2012

(54) Plasma Processing Apparatus

(75) Inventors: Hiroyuki Kobayashi, Kodaira (JP); Kenji Maeda, Kodaira (JP); Takumi Tandou, Hachioji (JP); Shoichi Nakashima, Hitachi (JP); Shigeru Ohno, Yokohama (JP)

(73) Assignee: Hitachi, Ltd., Chiyoda-ku (JP)

(21) Appl. No.: 13/521,467

(22) PCT Filed: Feb. 4, 2011
(86) PCT No.: PCT/JP2011/052344

§ 371 Date: Jul. 11, 2012

(30) Foreign Application Priority Data
Mar. 15, 2010 (JP) 2010-056909

(51) Int. Cl. C23C 16/50; C23C 16/52

(52) U.S. Cl. 118/712; 118/723 R

(57) ABSTRACT

Disclosed is a plasma processing apparatus which performs plasma processing under substantially atmospheric pressure to a non-planar subject to be processed. In the plasma processing apparatus, a pair of conductive wires are disposed at an interval of 1 mm or less on a dielectric board that conforms with the shape of the subject, the conductive wires are covered with a dielectric thin film having a thickness of 1 mm or less by, for instance, thermally spraying a dielectric material over the conductive wires, and plasma is generated along the shape of subject by applying high-frequency power to the pair of conductive wires.

### TECHNICAL FIELD

This invention relates to plasma processing apparatuses for film forming, surface reforming, cleaning and the like.

### BACKGROUND ART

Plasma technology has been widely used so far in etching, CVD (chemical vapor deposition), and the like in semiconductor manufacturing. Generally, these processes are performed under reduced pressure with the use of a vacuum chamber. On the other hand, recently a technology to generate plasma under atmospheric pressure has been examined, and in order to form functional films such as a DLC (diamond-like carbon) film, to remove organic matters from material surfaces, and to destroy bacteria, how to use plasma has been widely investigated. For example, Patent Literature 1 discloses a plasma processing apparatus that processes a substrate under atmospheric pressure. The plasma processing apparatus has a structure in which plural discharge electrode plates are arranged in parallel. In addition, Patent Literature 2 discloses a plasma processing apparatus that has a structure in which two types of electrodes are arranged in a way as if teeth of two types of combs face each other.

### CITATION LIST

### Patent Literature

Patent Literature 1: Japanese Unexamined Patent Application Publication No. 2005-135892
Patent Literature 2: Japanese Unexamined Patent Application Publication No. 2008-186832

### SUMMARY OF INVENTION

### Technical Problem

As a method for generating plasma under atmospheric pressure, there is a plasma-jet method that utilizes local discharge, or a line-type plasma method (Patent Literature 1) or a flat-plate-type plasma method (Patent Literature 2) for planar processing. The mean free path (lifetime) of ions or radicals generated in plasma is shorter in the case of the atmospheric pressure plasma method compared with in the case of the reduced pressure plasma method, and therefore it is necessary to set the distance between a substrate and the plasma shorter. Therefore, in order to perform plasma processing to a non-planar subject, a technique to generate plasma in a non-planar shape along the shape of the subject is required.

### Solution to Problem

Typical present inventions are as follows.

One invention is a plasma processing apparatus including: a cylindrical dielectric board; a pair of conductive wires disposed at an interval of 1 mm or less on the outer periphery of the dielectric board; and a dielectric film that has a thickness of 1 mm or less, and covers the pair of conductive wires.

Another invention is a plasma processing apparatus including: a cylindrical dielectric board; a pair of conductive wires disposed at an interval of 1 mm or less on the inner periphery of the dielectric board; and a dielectric film that has a thickness of 1 mm or less, and covers the pair of conductive wires.

In addition, another invention is a plasma processing apparatus including: plural dielectric boards; plural pairs of conductive wires disposed at an interval of 1 mm or less on the plural dielectric boards respectively; plural dielectric films that have a thickness of 1 mm or less, and cover the plural pairs of conductive wires respectively; and plural position adjusting mechanisms prepared for the plural dielectric boards respectively for adjusting distances to a subject and angles toward the subject respectively.

### Advantageous Effects of Invention

Because the present invention can generate plasma that conforms with the shape of a subject under substantially atmospheric pressure according to the present invention, uniform plasma processing can be performed to a non-planar subject.

### BRIEF DESCRIPTION OF DRAWINGS

FIG. 1 is a perspective view of a discharging unit of a plasma processing apparatus according to a first embodiment of the present invention.

FIG. 2 is a schematic view of the entirety of the plasma processing apparatus according to the first embodiment of the present invention.

FIG. 3 is a perspective view showing a film forming process with the use of the plasma processing apparatus according to the first embodiment of the present invention.

FIG. 4 is a cross-section view of substantial parts of a measuring system and a gas introducing system of the plasma processing apparatus according to the first embodiment of the present invention for illustrative purpose.

FIG. 5A is a perspective view showing another configuration of electrodes in the discharging unit of the plasma processing apparatus according to the first embodiment of the present invention.

FIG. 5B is a cross-section view of the discharging unit including the radius of a cylinder shown in FIG. 5A.

FIG. 6 is a perspective view showing another configuration of electrodes in the discharging unit of the plasma processing apparatus according to the first embodiment of the present invention.

FIG. 7 is a perspective view of a discharging unit of a plasma processing apparatus according to a second embodiment of the present invention.

FIG. 8 is a schematic view of the entirety of the plasma processing apparatus according to the second embodiment of the present invention.

FIG. 9 is a schematic view of a measuring system and a gas introducing system of the plasma processing apparatus according to the second embodiment of the present invention for illustrative purpose.

FIG. 10 is a schematic view of the entirety of a plasma processing apparatus according to a third embodiment of the present invention.

FIG. 11A is a top view of a discharging unit of the plasma processing apparatus according to the third embodiment of the present invention.

FIG. 11B is a cross-section view of substantial parts of the discharging unit of the plasma processing apparatus shown in FIG. 11A.

FIG. 12 is a diagram showing the arrangement of the discharging unit of the plasma processing apparatus according to the third embodiment of the present invention.

FIG. 13 is a cross-section view of substantial parts of a measuring system of the plasma processing apparatus according to the third embodiment of the present invention for illustrative purpose.

### DESCRIPTION OF EMBODIMENTS

According to the present invention, electrodes used for dielectric barrier discharge are formed by disposing two conductive wires substantially in parallel on a dielectric board, and by covering the pair of the conductive wires with a dielectric film, with the result that plasma along a non-planar shaped subject can be generated.

Hereinafter, practical examples of plasma processing apparatuses to which the present invention is applied will be explained in detail with reference to the accompanying drawings.

### First Embodiment

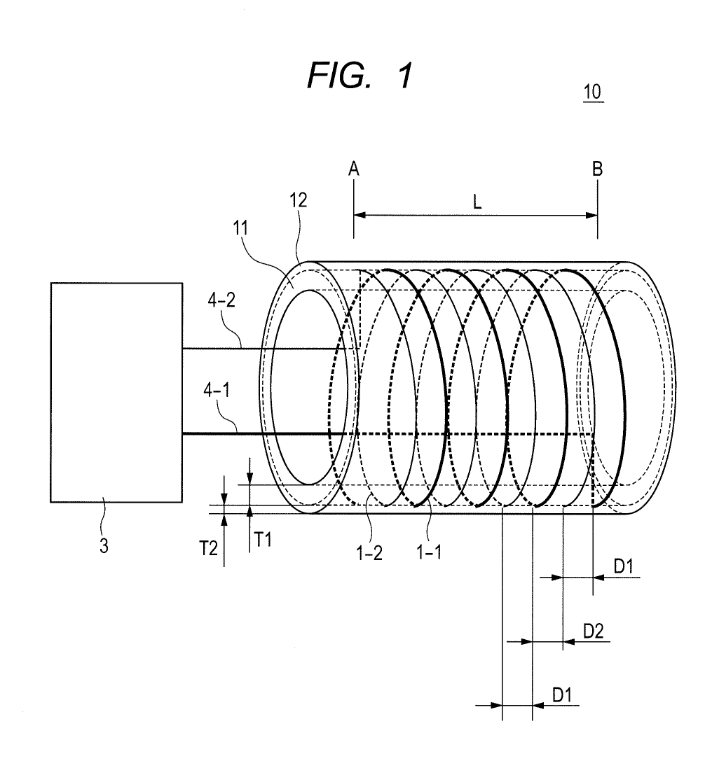

First, a first embodiment of the present invention will be described. FIG. 1 is a perspective view of a basic configuration example of a plasma source (plasma discharge unit) 10 for generating plasma in a processing apparatus that generates plasma along a cylindrical outer periphery. The left aperture of the cylindrical plasma source is visible, while the right aperture is invisible and is shown by a dotted line. Two conductive wires 1-1 and 1-2 are wound around a cylindrical dielectric board 11 in a spiral way while the two conductive wires 1-1 and 1-2 are kept substantially in parallel with each other. In addition, the two conductive wires 1-1 and 1-2 are covered with a dielectric film 12 having a thickness (T2) of 1 mm or less. These conductive wires covered with the dielectric film forms electrodes used for dielectric barrier discharge. In FIG. 1, the two conductive wires 1-1 and 1-2 are depicted with two curved lines whose line widths are different from each other. Parts of the two lines on the back side viewed from this side are depicted with dotted lines. The interval D1 between the two conductive lines is set 1 mm or less. In addition, if the two wires are disposed substantially in parallel, it is desirable that the gap D2 between two adjacent intervals D1 and D1 is larger than the interval D1. This is because, the shorter a gap between parts of the conductive wires 1-1 and 1-2 is, the more easily discharge occurs at the gap. In addition, more steadier discharge can be obtained at the gap. It is desirable that raw material for the dielectric board 11 and the dielectric film 12 has high plasma resistance. For example, it is desirable that glass, transparent yttria, or alumina (Al₂O₃) is used as the raw material. Depending on processes to be performed, resin or the like can be used as raw material for the dielectric board and the dielectric film.

As shown in FIG. 1, the right end (around B in FIG. 1) of one of the two wires (1-1) is connected to a high frequency power source 3 via the conductive wire 4-1, and the left end (around A in FIG. 1) is terminated on the board 11. On the other hand, the left end of the other of the two wires (1-2) is connected to the high frequency power source 3 via the conductive wire 4-2, and the right end is terminated on the board 11. The above configuration makes a plasma density distribution during the interval of length L as even as possible. There is a possibility that the plasma density distribution becomes uneven if both wires are terminated on the same side of the board 11. A configuration in which the middle points between the left ends (A in FIG. 1) and the right ends (B in FIG. 1) of the two wires are connected to the high frequency power source 3 respectively is conceivable. In this configuration, however, there is a possibility that the plasma density relatively becomes large in the vicinity of the middle point of the interval of length L. Therefore, the configuration shown in FIG. 1 is more preferable. In addition, it is necessary that the thickness (T1) of the board 11 is thicker than the thickness (T2) of the dielectric film 12. This setting is done in order to generate plasma discharge at the cylindrical exterior. Although it is possible to generate plasma discharge at the cylindrical exterior in principle if T1 is larger than T2, it is desirable that T1 is ten times as large as T2 or larger in consideration of the strength of the board. Here, the high frequency power source 3 is a high frequency power source with its frequency 1 kHz to 1 MHz.

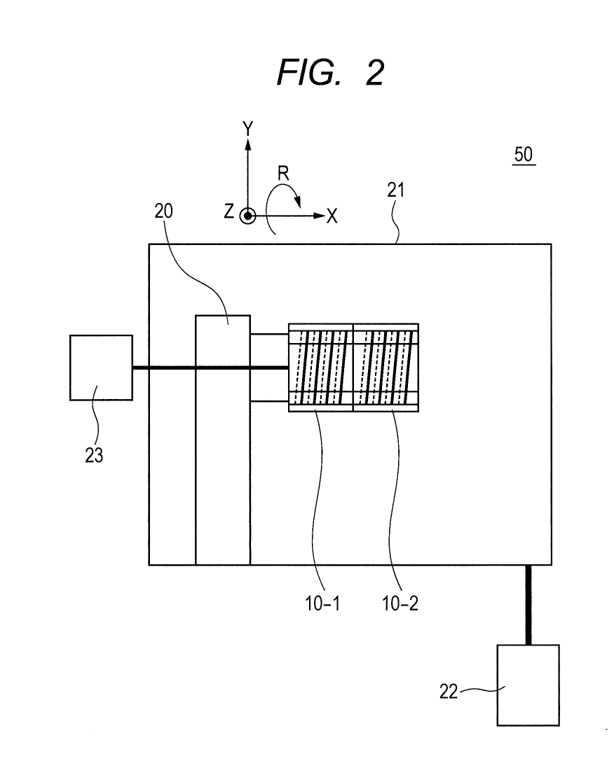

FIG. 2 shows an example of the outline of the entirety of the plasma processing apparatus 50 that employs the plasma source shown in FIG. 1. In this example, the plasma source 10 (10-1 and 10-2) connected in series so as to make it possible that the length of the subject to which plasma processing is performed becomes longer. The plasma source 10 is connected to a position adjusting mechanism 20, and the plasma source 10 (10-1 and 10-2) can be moved in the X, Y, Z, and R directions. A processing gas supply system 23 for supplying processing gas and an exhaust system 22 for exhausting the processing gas are connected to a processing chamber 21. For example, if a silicon-type film is formed by plasma, a silane-type gas is used, if a DLC film is formed, a hydrocarbon-type gas is used, and if cleaning is performed, a mixed gas whose main component is an oxygen gas is used. In addition, it is desirable that the plasma source 10-2 uses a high frequency power source 3 different from a high frequency power source 3 that the plasma source 10-1 uses, although these high frequency power sources are not shown in FIG. 2. This is because, if conductive wires used for connecting the plasma source 10 to the high frequency power source 3 become too long, a high output power is required of the high frequency power source 3, therefore the cost for the high frequency power source 3 goes up.

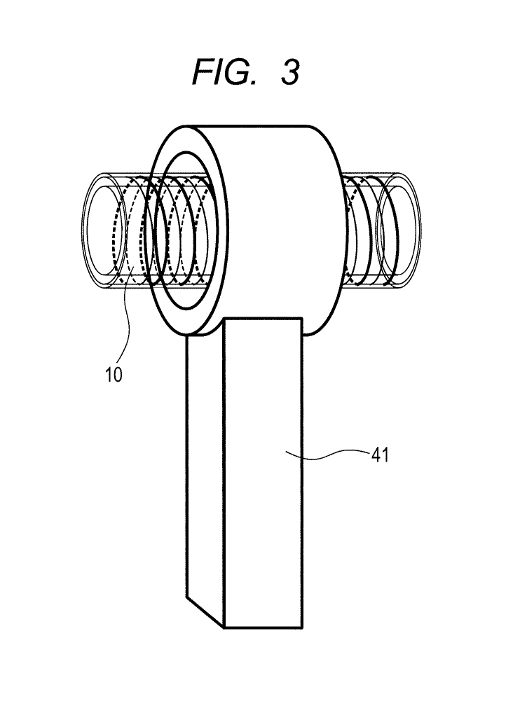

FIG. 3 is a perspective view showing, as an example of film forming process, a process of forming a DLC film inside a bearing that a subject 41 has as a part of its structure. In order to form the DLC film evenly inside the circular bearing, the cylindrical plasma source 10 is inserted into the inside of the bearing, and the film forming process is carried out by generating plasma in a space between the cylindrical plasma source 10 and the bearing.

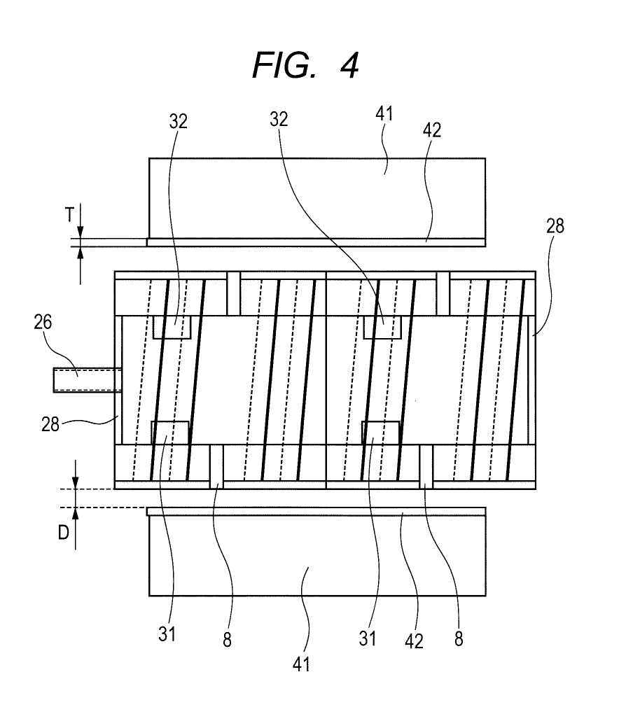

FIG. 4 is a cross-section view of substantial parts of the components shown in FIG. 3 used for describing the outline of a measuring system installed in the plasma source 10. Inside the plasma source 10, plural distance meters 31 used for measuring distances to the subject 41 are installed along the inner circumference. These distance meters are installed in order to conform the center of the aperture circle of the subject 41 to the center of the cylinder of the plasma source 10, and to perform plasma processing evenly to the inner surface of the subject 41. In FIG. 4, however, only one distance meter per plasma source is depicted. The position adjusting mechanism 20 (See FIG. 2) adjusts the position of the plasma source 10 on the basis of information obtained by the distance meters 31 so that the distance between the subject and the plasma source is kept to be a predetermined distance. In addition, film thickness monitors 32 are installed inside the plasma source 10. If both dielectric board 11 and thin film 12 are substantially transparent, that is, if the dielectric board 11 and the dielectric film 12 are made of glass, transparent yttria, or the like, the film thickness of a formed functional film 42 can be detected by observing interference waveforms generated owing to the formed functional film 42 with the use of plasma lights or externally incident lights irradiated from the film thickness monitors 32. The plural film thickness monitors are disposed along the inner circumference of the plasma source 10 just like the distance meters. In FIG. 4, however, only one film thickness monitor per plasma source is depicted.

The processing gas is supplied through gas holes 8 to the outer periphery of the cylinder, and the processing gas can be held inside the cylinder by getting lids 28 on both ends of the plasma source 10. Although the lids 28 are not indispensable components, the processing gas can be evenly supplied to the outer periphery owing to the function of the lids 28.

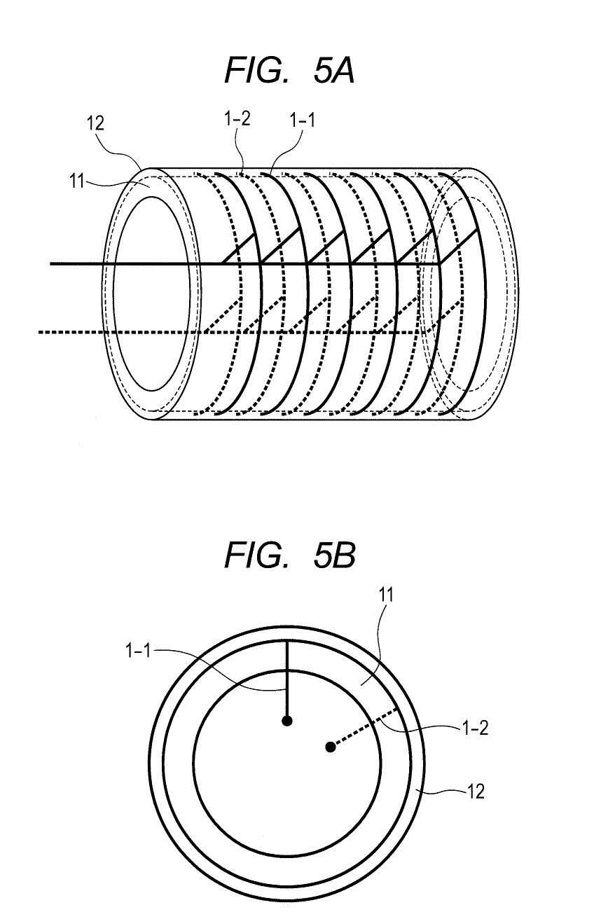

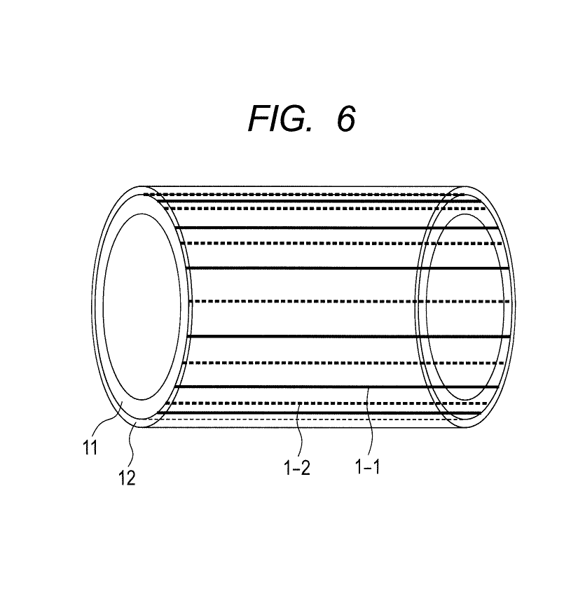

In this embodiment, although the above description has been made about the configuration in which two conductive wires are disposed substantially in parallel in a spiral way, a configuration shown in FIG. 5 or FIG. 6 can also be used. FIG. 5A shows a method in which two types of electrodes (1-1 and 1-2) are alternately disposed along the circumference of the board 11. FIG. 5B is a cross section view of the components shown in FIG. 5A including a radius of the cylinder. In addition, a method in which two types of electrodes are alternately disposed in the length direction of the cylinder as shown in FIG. 6 can also be used. In the case shown in FIG. 5 or FIG. 6, plural outgoing wires are required, hence the structure of the plasma source becomes complex. On the other hand, in the case of FIG. 1 where two conductive wires are disposed in a spiral way, one outgoing wire (4-1 or 4-2) per conductive wire is required, hence there is an advantage that the structure is simple.

### Second Embodiment

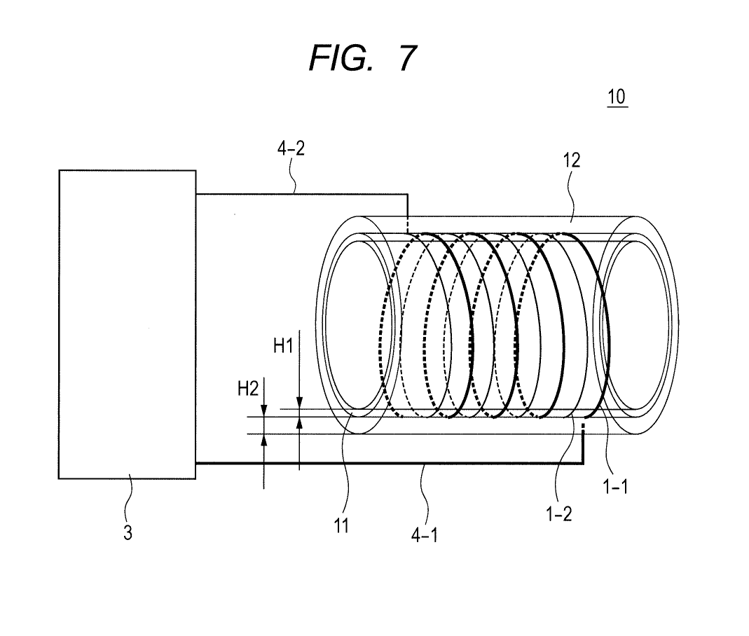

Next, as a second embodiment, a plasma processing apparatus in which a cylindrical plasma source generates plasma at the inner periphery of the cylinder will be described hereinafter. FIG. 7 is a perspective view showing a plasma source 10 that generates plasma at the inner periphery of the cylinder. In FIG. 7, two conductive wires are wound around a cylindrical dielectric board 11 in a spiral way while the two conductive wires are kept substantially in parallel with each other just like in FIG. 1. In addition, a dielectric film 12 is formed on the two conductive wires. In this embodiment, however, in order for plasma to be generated inside the cylinder, the thickness H1 of the dielectric board 11 is set sufficiently thinner than the thickness H2 of the dielectric film 12. For example, the thickness H1 of the dielectric board is 1 mm or less, and the thickness H2 of the dielectric film is ten times H1 or more. Although, if H1 is thinner than H2, it is possible to generate plasma inside the dielectric board 11 in principle, H2 is set ten times H1 or more in consideration of the strength of the board just like in the case of the first embodiment. In addition, although the above description has been made under the assumption that the inside part of the cylinder is the dielectric board 11 and the outside part of the cylinder is the dielectric film 12, the similar description can be made under the assumption that the inside part of the cylinder is the dielectric film 11 and the outside part of the cylinder is the dielectric board 12. There is a difference between these manufacturing methods, but the resultant plasma sources have the same effect. In addition, outgoing wires 4-1 and 4-2 from the spirally wounded conductive wires are set to be drawn outside the cylinder. The way in which the outgoing wires 4-1 and 4-2 terminate at the board, and the way in which the outgoing wires 4-1 and 4-2 are connected to a high frequency power source 3 are the same as those in the case of the first embodiment, and hence their descriptions will be omitted.

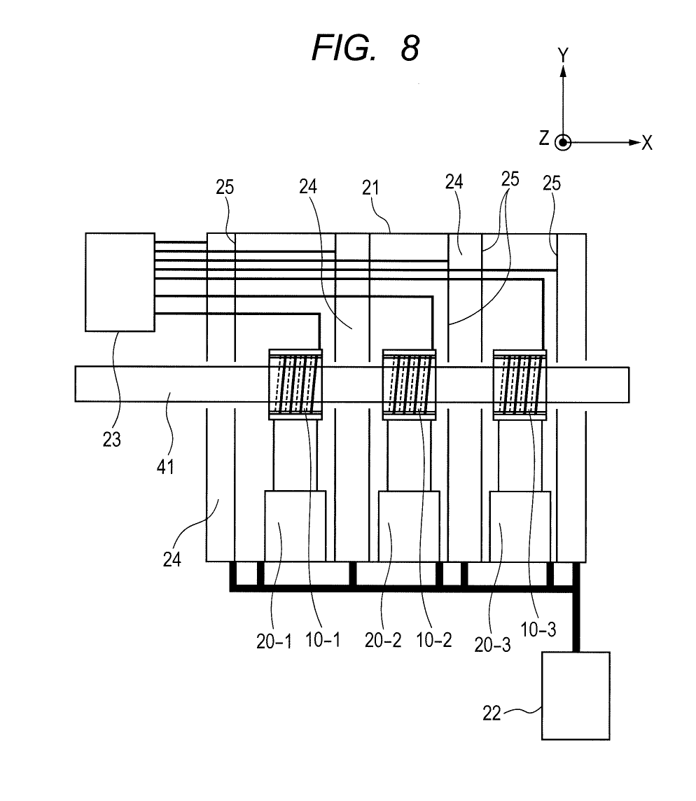

FIG. 8 shows the outline of the entirety of the plasma processing apparatus. This apparatus performs, for example, a film forming process to a rod-like subject 41 such as an electric wire, and has a processing chamber 21, and three plasma sources 10 in the processing chamber 21. This apparatus performs the film forming process while moving the subject 41 in the X direction. For example, the apparatus performs cleaning using the plasma source 10-1, surface reforming using the plasma source 10-2, and film forming using the plasma source 10-3. The plasma sources 10 are install in position adjusting mechanisms 20 (20-1, 20-2, and 20-3) respectively, so that each of the distances to the subject 41 can be adjusted. A processing gas supply system 23 for supplying processing gas and an exhaust system 22 for exhausting the processing gas are installed in the processing chamber 21. As for the processing gas, an oxygen gas is supplied to the plasma source 10-1 that is in charge of the cleaning process, a hydrogen gas or the like to the plasma source 10-2 that is in charge of the surface reforming process, and a hydrocarbon-type gas to the plasma source 10-3 that is in charge of the film forming process. Needless to say, a nitrogen gas or noble gases can be used as a dilution gas in these processes. By supplying a nitrogen gas between two partition plates 25 set up at the left end and the right end of each plasma source, gas exchange regions 24 are built in the processing chamber 21. The above description has been made under the assumption that the processes are performed while the subject 41 is moved in the X direction. However, the same processes can be performed under the design that the plasma source itself is moved in the minus X direction.

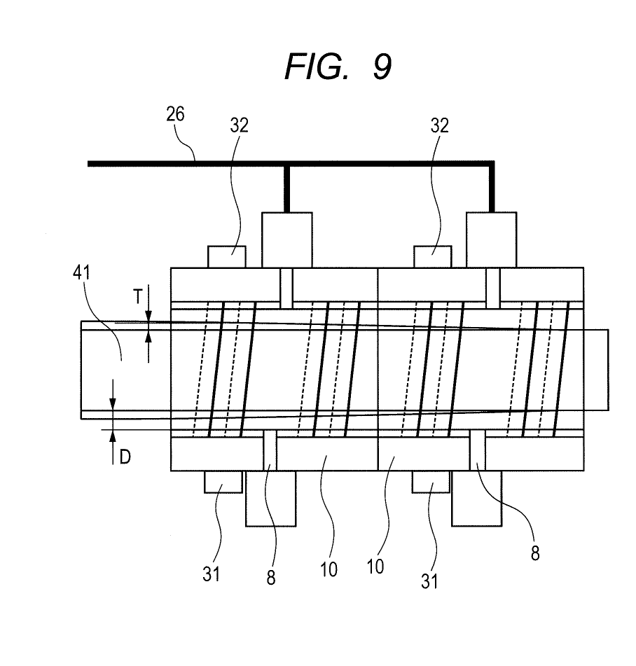

FIG. 9 is a cross-section view of substantial parts of the components shown in FIG. 7 used for describing a measuring system and a gas introducing system installed in the plasma source 10. In FIG. 9, it is assumed that the plasma source has a structure that includes two plasma sources connected in series just like the first embodiment shown in FIG. 2. Plural distance meters 31 for measuring distances (D) to a subject are installed at the outer periphery of each of the two plasma sources 10 along the circumference. In FIG. 9, however, only one distance meter per plasma source is depicted. In addition, plural film thickness monitors 32 for measuring thicknesses (T) of a film formed on the subject are installed along the outer circumference of each of the two plasma sources 10. In FIG. 9, however, only one film thickness meter per plasma source is depicted. FIG. 9 shows that the subject 41 is moving left relative to the plasma sources 10, and further shows that the more left part of the formed film lies, the thicker the part is. In addition, the processing gas is supplied to the inside of the cylinder via a gas line 26 and gas holes 8. In this embodiment, although the configuration in which two conductive wires are disposed in a spiral way has been described, other configurations can also be used. In the case where two conductive wires are disposed in a spiral way, one outgoing wire per conductive wire is required; hence, there is an advantage that the structure is simple.

### Third Embodiment

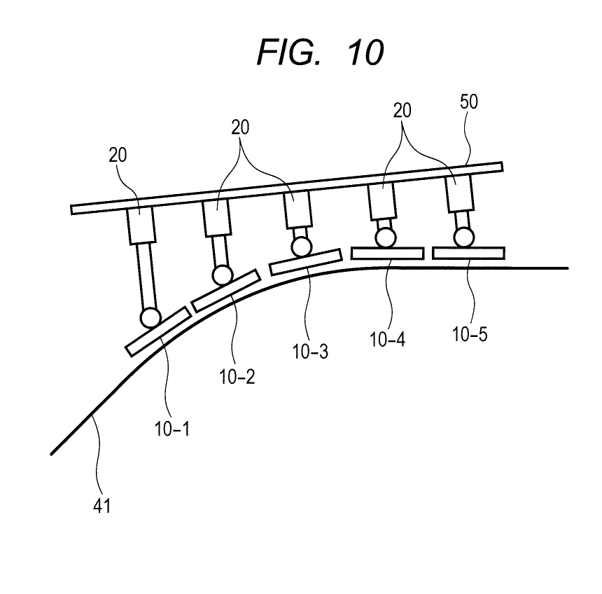

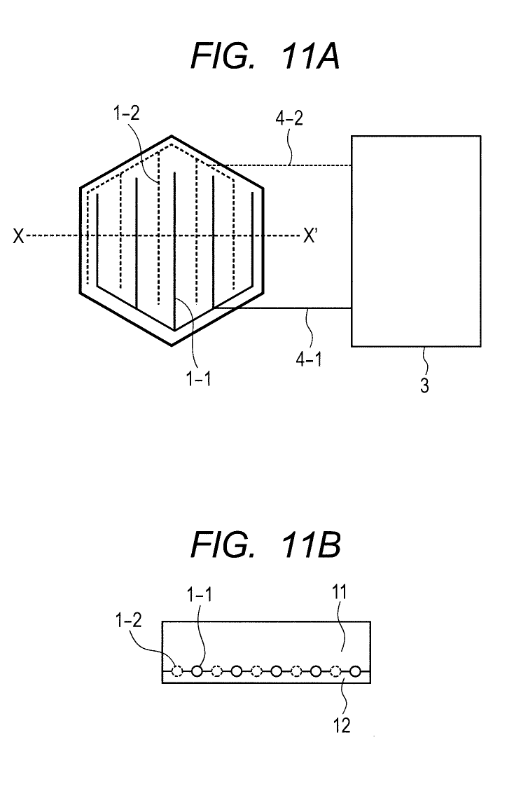

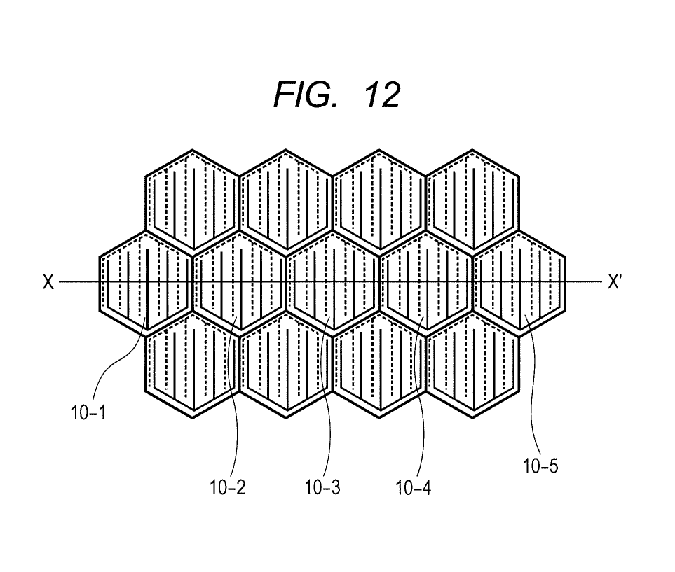

Next, as a third embodiment, a plasma processing apparatus in which plasma processing is performed to a large-sized non-planar subject will be described. FIG. 10 shows the outline of the entirety of a plasma processing apparatus 50 according to the present invention. Flat-plate-type plasma sources 10 (10-1 to 10-5) are connected to position adjusting mechanisms 20 respectively, and distances to the subject and directions (angles) toward the subject can be adjusted. FIG. 11 (11A and 11B) shows an example of the plasma sources 10. FIG. 11A shows a top view, and FIG. 11B shows a cross-section view. Two types of wires 1-1 and 1-2 are disposed substantially in parallel, and a dielectric film 12 is formed on the wires, and hence electrodes covered with the dielectric film are formed. The thickness of the dielectric film 12 is 1 mm or less, and the thickness of the dielectric board 11 is set to be ten times the thickness of the dielectric film 12 or more in order to secure the strength of the electrodes. The electrodes 1-1 and 1-2 are connected to a high frequency power source 3 via outgoing wires 4-1 and 4-2 respectively. FIG. 12 shows a top view of the arranged flat-plate-type plasma sources 10. A cross section view taken from line X-X′ in FIG. 12 corresponds to the plasma sources in FIG. 10. Here, although the shape of each plasma source is a hexagon in order to densely dispose the plasma sources, the shape of each plasma source is not limited to a hexagon, and can be a pentagon or a square.

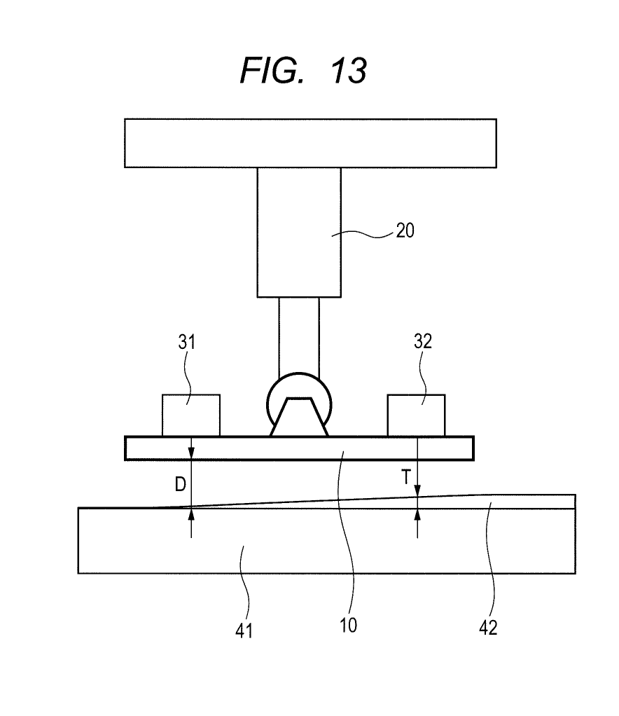

FIG. 13 is a diagram for describing a monitor system installed in one of the flat-plate-type plasma sources. FIG. 13 shows that the subject 41 is moving right relative to the plasma source 10, and further shows that the more right part of the formed film lies, the thicker the part is. Just like in the case of the first embodiment or the second embodiment, a distance meter 31 for measuring a distance to a subject is installed, and a distance D between the plasma source 10 and the board 41 is measured via the dielectric film 12 and the dielectric board 11. Next, the position adjusting mechanism 20 adjusts the distance between the subject 41 and the plasma source 10 and the direction (angle) toward the subject on the basis of the obtained information. In this embodiment, it is assumed that the subject is non-planar while the plasma source is planar, and therefore the direction as well as the distance must be adjusted. In addition, a film thickness monitor 32 is installed in the plasma source 10. Plasma light or externally incident light irradiated from the film thickness monitors 32 reaches the functional film 42 through the dielectric film 12 and the dielectric board 11. The thickness of a film formed on the subject 41 can be detected by observing an interference waveform generated at the functional film 42 by the plasma light or the externally incident light. Here, although only one distance meter 31 and only one film thickness monitor 32 are depicted in FIG. 13, actually two or more distance meters 31 are disposed because two or more distance meters are necessary for the position adjusting mechanism 20 to adjust the direction of the plasma source.

In addition, each of the plasma sources (10-1 to 10-5) shown in FIG. 10 has a high frequency power source 3 as shown in FIG. 11A. If a high frequency power source common to all the plasma sources is used, a large-sized high frequency power source is required, which leads to high costs of the high frequency power source. In addition, an advantage to each plasma source having a high frequency power source is that one or more suitable plasma sources can be selected for plasma processing on the basis of various conditions such as the shape of a subject and the amount of a film to be formed.

As described above in detail about the first to third embodiments, the present invention makes it possible to perform plasma processing to a non-planar subject under substantially atmospheric pressure.

In the plasma processing apparatus according to the present invention, a pair of conductive wires are disposed at an interval of 1 mm or less on a dielectric board that conforms with the shape of the subject, the conductive wires are covered with a dielectric thin film having a thickness of 1 mm or less by, for instance, thermally spraying a dielectric material over the conductive wires, and plasma is generated along the shape of the subject by applying high-frequency power to the pair of conductive wires.

### LIST OF REFERENCE SIGNS

1: Electrode, 3: High frequency Power Source, 4: Wire, 8: Gas Hole, 10: Plasma Source (Plasma Discharge Unit), 11: Dielectric Board, 12: Dielectric Film, 20: Position Adjusting Mechanism, 21: Processing Chamber, 22: Exhaust System, 23: Processing Gas Supply System, 24: Gas Exchange Region, 25: Partition Plate, 26: Gas Line, 28: Lid, 31: Distance Meter, 32: Film Thickness Monitor, 41: Subject, 42: Functional Film, 50 Plasma Processing Apparatus

1. A plasma processing apparatus comprising:
a cylindrical dielectric board;
a pair of conductive wires disposed at an interval of 1 mm or less on the outer periphery of the dielectric board; and
a dielectric film having a thickness of 1 mm or less, the dielectric film covering the pair of conductive wires.

2. The plasma processing apparatus according to claim 1, wherein the pair of conductive wires are disposed substantially in parallel.

3. The plasma processing apparatus according to claim 1, further comprising a position adjusting mechanism for driving the dielectric board.

4. The plasma processing apparatus according to claim 1, further comprising a distance meter for measuring a distance to a subject disposed outside the dielectric board, the distance meter being disposed inside the dielectric board.

5. The plasma processing apparatus according to claim 1, further comprising a film thickness monitor for measuring the thickness of a film, which is formed on a subject disposed outside the dielectric board with the use of plasma, the film thickness monitor being disposed inside the dielectric board.

6. The plasma processing apparatus according to claim 1, further comprising:
a position adjusting mechanism for driving the dielectric board; and
a plurality of measuring instruments for measuring a distance to a subject disposed outside the dielectric board, the measuring instruments being disposed inside the dielectric board, wherein the position adjusting mechanism drives the dielectric board on the basis of distance information obtained by the plurality of measuring instruments so that the distance between the dielectric board and the subject is kept to be a predetermined distance.

7. The plasma processing apparatus according to claim 1, wherein the pair of conductive wires are so disposed as to be wound around the dielectric board in a spiral way.

8. The plasma processing apparatus according to claim 1, further comprising a high frequency power source for applying an alternating voltage to the pair of conductive wires.

9. A plasma processing apparatus comprising:
a cylindrical dielectric board having a thickness of 1 mm or less;
a pair of conductive wires disposed at an interval of 1 mm or less on the outer periphery of the dielectric board; and
a dielectric film covering the pair of conductive wires.

10. The plasma processing apparatus according to claim 9, wherein the pair of conductive wires are disposed substantially in parallel.

11. The plasma processing apparatus according to claim 9, further comprising a position adjusting mechanism for driving the dielectric board.

12. The plasma processing apparatus according to claim 9, further comprising a distance meter for measuring a distance to a subject disposed inside the dielectric board, the distance meter being disposed outside the dielectric board.

13. The plasma processing apparatus according to claim 9, further comprising a film thickness monitor for measuring the thickness of a film, which is formed on a subject disposed inside the dielectric board with the use of plasma, the film thickness monitor being disposed outside the dielectric board.

14. The plasma processing apparatus according to claim 9, further comprising:
a position adjusting mechanism for driving the dielectric board; and
a plurality of measuring instruments for measuring a distance to a subject disposed inside the dielectric board, the measuring instruments being disposed outside the dielectric board, wherein the position adjusting mechanism drives the dielectric board on the basis of distance information obtained by the plurality of measuring instruments so that the distance between the dielectric board and the subject is kept to be a predetermined distance.

15. The plasma processing apparatus according to claim 9, wherein the pair of conductive wires are so disposed as to be wound around the dielectric board in a spiral way.

16. The plasma processing apparatus according to claim 9, further comprising a high frequency power source for applying an alternating voltage to the pair of conductive wires.

17. A plasma processing apparatus comprising:
a plurality of dielectric boards;
a plurality pairs of conductive wires disposed at an interval of 1 mm or less on the plurality of dielectric boards respectively;
a plurality of dielectric films having a thickness of 1 mm or less, the plurality of dielectric films covering the plurality of pairs of conductive wires respectively; and
a plurality of position adjusting mechanisms prepared for the dielectric boards respectively, wherein each position adjusting mechanism adjusts a distance to a subject and an angle toward the subject.

18. The plasma processing apparatus according to claim 17, wherein each of the plurality of pairs of conductive wires are disposed substantially in parallel.

19. The plasma processing apparatus according to claim 17, wherein
the plurality of dielectric boards further includes a plurality of measuring instruments for measuring distances to a subject respectively; and
the position adjusting mechanisms drive the dielectric boards respectively on the basis of distance information obtained by the plurality of measuring instruments so that the distances between the dielectric boards and the subject are kept to be a predetermined distance.

20. The plasma processing apparatus according to claim 17, further comprising high frequency power sources for applying alternating voltages to the plurality of pairs of conductive wires respectively.
